(19) United States
(12) Patent Application Publication
(10) Pub. No.: US 2023/0317793 A1
(43) Pub. Date: Oct. 5, 2023

(54) STACKED FIELD EFFECT TRANSISTORS WITH REDUCED GATE-TO-DRAIN PARASITIC CAPACITANCE

(71) Applicant: International Business Machines Corporation, Armonk, NY (US)

(72) Inventors: Shogo Mochizuki, Mechanicville, NY (US); Gen Tsutsui, Albany, NY (US)

(21) Appl. No.: 17/709,628

(22) Filed: Mar. 31, 2022

(51) Int. Cl. H01L 29/10; H01L 29/06; H01L 29/66

(52) U.S. Cl. CPC H01L 29/1033; H01L 29/0665; H01L 29/0653; H01L 29/6653; H01L 29/66545

(57) ABSTRACT

An inner field effect transistor has an inner source, an inner drain, and a group of inner nanosheet channel structures interconnecting the inner source and the inner drain. An outer field effect transistor has an outer source, an outer drain, and a group of outer nanosheet channel structures interconnecting the outer source and the outer drain. An isolation region is located between the inner field effect transistor and the outer field effect transistor. A metal gate stack is located between the inner source and inner drain and between the outer source and the outer drain. The metal gate stack at least partially surrounds the inner and outer nanosheet channel structures. The metal gate stack has a dielectric region adjacent the isolation region.

### BACKGROUND

The present invention relates generally to the electrical, electronic and computer arts and, more particularly, to stacked field effect transistors.

The well-known field-effect transistor (FET) is a device that uses an electric field to control the flow of current in a semiconductor, and typically includes source, gate, drain (and body) terminals. FET devices control the flow of current by the application of a voltage to the gate, which in turn alters the conductivity in the channel between the drain and source.

The fin-type field effect transistor (FinFET) is a multi-gate device, built on a substrate, with the gate placed on two or more sides of the channel or wrapped around the channel, thus forming a multiple-gate structure. FinFET devices have significantly faster switching times and higher current density than planar CMOS (complementary metal-oxide-semiconductor) FET technology.

Further advances beyond FinFETs have been proposed in the form of semiconductor nanowires employed as metal-oxide-semiconductor field-effect transistor (MOSFET) channels which can enable a gate-surrounding structure allowing good electrostatic gate control over the channel for reducing short-channel effects. Similar to lateral nanowire FETs, nanosheet FETs use wider and thicker wires to provide improved electrostatics and drive current.

FET devices can be vertically stacked to increase the density of the FETs on a silicon die.

### BRIEF SUMMARY

Principles of the invention provide structures for stacked field-effect transistors. In one aspect, an exemplary semiconductor structure includes an inner field effect transistor having an inner source, an inner drain, and a group of inner nanosheet channel structures interconnecting the inner source and the inner drain; an outer field effect transistor having an outer source, an outer drain, and a group of outer nanosheet channel structures interconnecting the outer source and the outer drain; an isolation region between the inner field effect transistor and the outer field effect transistor; and a metal gate stack between the inner source and inner drain and between the outer source and the outer drain, the metal gate stack at least partially surrounding the inner and outer nanosheet channel structures, the metal gate stack having a dielectric region adjacent the isolation region.

In another aspect, an exemplary method of forming a semiconductor structure includes providing a precursor structure comprising a plurality of nanosheet stacks on a substrate, the nanosheet stacks being separated by a plurality of gaps partially filled with shallow trench isolation material, the nanosheet stacks comprising alternating layers of nanosheets and spacers, including a central selectively etchable region. Additional steps include forming dummy gate structures and gate spacers crosswise to the plurality of nanosheet stacks; etching back the nanosheet stack even with the gate spacers; and selectively etching back the central selectively etchable region to form an etched-back area, and filling the etched-back area with dielectric material.

As used herein, “facilitating” an action includes performing the action, making the action easier, helping to carry the action out, or causing the action to be performed. Thus, by way of example and not limitation, instructions executing on a processor might facilitate an action carried out by semiconductor fabrication equipment, by sending appropriate data or commands to cause or aid the action to be performed. Where an actor facilitates an action by other than performing the action, the action is nevertheless performed by some entity or combination of entities.

Techniques as disclosed herein can provide substantial beneficial technical effects. By way of example only and without limitation, one or more embodiments may provide one or more of:
stacked nanosheet (stacked-NS) device architectures for complementary metal-oxide semiconductor (CMOS) logic integration;
structures that improve parasitic capacitance in stacked-NS device architectures for maximizing alternating current (AC) performance; and
ability to locate a void, such as an air gap, in a dielectric material, which advantageously provides the ideally lowest permittivity.

Some embodiments may not have these potential advantages and these potential advantages are not necessarily required of all embodiments. These and other features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1A illustrates pertinent aspects of the physical structure of conventional stacked field-effect transistors (FETs);

FIG. 1B illustrates pertinent structural changes in exemplary stacked field-effect transistors, in accordance with an example embodiment;

FIG. 2A shows a top view of an exemplary stacked field-effect transistors, in accordance with an example embodiment;

FIG. 2B is a cross-section along line A-A′ in FIG. 2A;

FIG. 2C is a cross-section along line B-B′ in FIG. 2A;

FIG. 2D is a cross-section along line C-C′ in FIG. 2A;

FIG. 3A illustrates a view of a nanosheet stack (NS) along the nanosheet stack cross section, in accordance with an example embodiment;

FIG. 3B illustrates a view of the nanosheet stack (NS) across the nanosheet stack cross section, illustrating a gate and spacer formation, in accordance with an example embodiment;

FIG. 3C illustrates a view of the nanosheet stack (NS) following reactive ion etching (RIE), in accordance with an example embodiment;

FIG. 3D illustrates a view of the nanosheet stack (NS) of FIG. 3C, following selective etching, in accordance with an example embodiment;

FIG. 3E illustrates a view of the nanosheet stack (NS) of FIG. 3C after selective etching and void formation, in accordance with an example “air gap” embodiment;

FIG. 4A replicates the physical structure of the conventional stacked field-effect transistor (FET) structure of FIG. 1A with the addition of an identification of the PC-CA overhang;

FIG. 4B is a graph that illustrates the impact of PC-CA overhang on the total effective capacitance Car in prior art devices;

FIG. 5 shows a more extensive view similar to FIG. 3A; and

FIG. 6 is a simplified schematic of a CMOS circuit including a plurality of stacked CMOS pairs.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

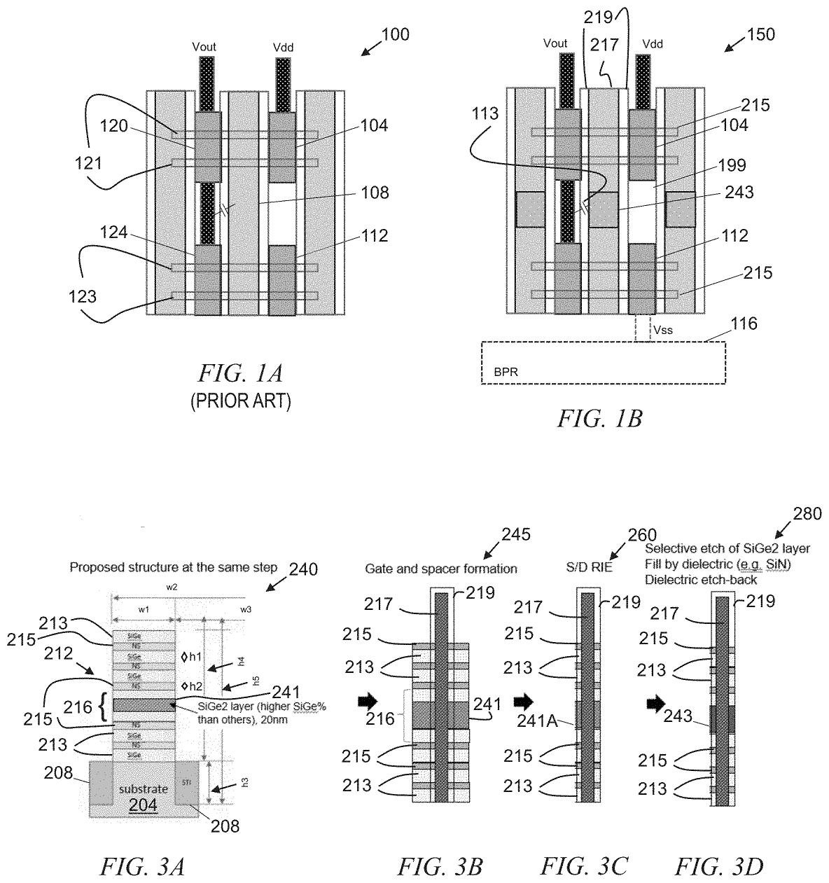

FIG. 1A illustrates pertinent aspects of the physical structure of a conventional stacked field-effect transistor (FET) structure 100 in a cross-sectional elevation (side view). The stacked-FET structure 100 includes two stacked FET devices. The top FET device (pFET) includes a source 104 and a drain 120 and the bottom FET device (nFET) includes a drain 124 and a source 112. Note the nanosheets 121 in the top device and 123 in the bottom device, as well as the gate 108. The nanosheets form conductive channels between source and drain when activated by the gate. The source 104 of the top FET is coupled to power (Vdd) and the output (Vout) is provided as shown. The stacked devices form a complementary metal oxide semiconductor (CMOS) inverter wherein the source 104 of the upper (pFET) device connects to Vdd, the source 112 of the lower (nFET) device connects to Vss, the input is applied to the common gate 108, and the (inverted) output Vout is taken at the node where the drain 120 of the upper (pFET) device connects to the drain 124 of the lower (nFET) device. Note that the Vss contact does not appear in the cross-sectional view of FIG. 1A, but would be seen, for example, in a top down view.

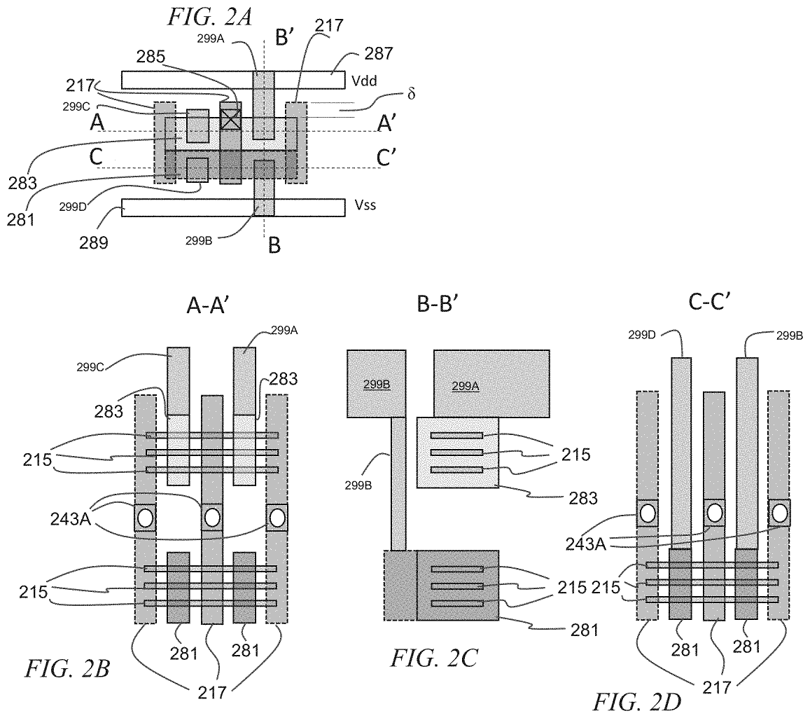

FIG. 1B illustrates pertinent structural changes in an example stacked field-effect transistor structure 150, in accordance with an example embodiment (as compared to the prior art device of FIG. 1A). Certain elements present in both FIG. 1A and FIG. 1B are not numbered in FIG. 1B to avoid clutter. Also, note that FIG. 1B is presented in a simplified, semi-schematic manner to facilitate side-by-side comparison with FIG. 1A and attention should be given to more detailed FIGS. 2A-2D, discussed below, for exemplary specific details (e.g., contacts). As illustrated by the capacitive representation 113 in FIG. 1B, the gate-to-drain capacitance is improved by replacing a portion of the conventional metal gate stack 108 of FIG. 1A (e.g., the portion adjacent the isolation region 199 between the nFET and the pFET) by a dielectric 243, such as silicon nitride (SiN). The inventive gate structure is designated as 217. Note also the gate spacers 219. The exemplary stacked-FET structure 150 includes one or more buried power rails (BPR) 116 (illustrated schematically); however, note that use of BPR 116 is optional. In view 150 and hereafter, the upper and lower nanosheets are designated as 215. Dielectric 243 could also have a void as discussed elsewhere with regard to dielectric 243A.

FIG. 2A illustrates a detailed plan or layout view of a stacked-FET structure, in accordance with an example embodiment. The dashed line labeled A-A′ represents a first cross-sectional view of the layout as shown in FIG. 2B (gate spacers are omitted to avoid clutter), the dashed line labeled B-B′ represents a second cross-sectional view of the layout as shown in FIG. 2C, and the dashed line labeled C-C′ represents a third cross-sectional view of the layout as shown in FIG. 2D. Note that FIGS. 2B and 2D show dielectrics 243A with voids but the depicted dielectrics could also be voidless dielectrics 243. In the top view of FIG. 2A, note the voltage rails Vdd 287 and Vss 289 (formed, for example, in M1/metal layer 1). Elements 299A, 299B, 299C and 299D are electrically conductive contact material such as copper, tungsten, or other metal. Note the nanosheets 215 forming channels, the gates 217, the upper source/drain epitaxy 283, the gate contact 285 (in a non-limiting example, a self-aligned contact) and the lower source/drain epitaxy 281. Note that an element like 243 (substituted dielectric portion of gate such as SiN) is not visible in the top down image of FIG. 2A but can be seen in FIGS. 2B and 2D. As best seen in FIG. 2B, the top FET device (pFET) includes a source (rightmost epitaxy 283 coupled to Vdd by contact 299A) and a drain (leftmost epitaxy 283 coupled to the drain of the bottom FET) and the bottom FET device (nFET) includes a drain (leftmost epitaxy 281) and a source (rightmost epitaxy 281 coupled to Vss by contact 299B as best seen in FIG. 2C). Thus, as in FIGS. 1A and 1B, the stacked devices form a complementary metal oxide semiconductor (CMOS) inverter wherein the source of the upper (pFET) device connects to Vdd, the source of the lower (nFET) device connects to Vss, the input is applied to the common (middle) gate 217 (e.g., by contact 285), and the (inverted) output Vout is taken at the node where the drain of the upper (pFET) device connects to the drain of the lower (nFET) device. Note the contacts 299D to the drain of the bottom nFET and 299C to the drain of the top pFET; suitable additional metallization (M1 or other metal layer) can be provided to connect those contacts and form the output node of the inverter (omitted for clarity).

The skilled artisan will be familiar with current techniques for forming CMOS stacked transistors, which do not include dielectrics 243, 243A. Such techniques typically include forming a conventional Si/SiGe epitaxy stack; carrying out Si/SiGe nanoribbon fin patterning; patterning polysilicon dummy gates; forming gate spacers; and epitaxially growing bottom and top source-drain regions. Such techniques typically further include depositing and polishing interlayer dielectric; removing the polysilicon dummy gates; releasing the Si nanoribbons (via SiGe etching); high-k deposition and formation of vertically stacked dual metal gates; etching for inner, outer, and inverter contacts; and filling contact metal and carrying out chemical-mechanical polishing.

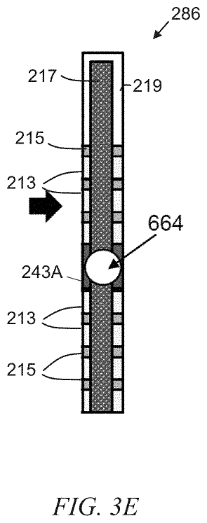

FIGS. 3A-3D illustrate pertinent aspects of a process flow for manufacturing an example stacked field-effect transistor structure, in accordance with an example embodiment. Distinctions from the prior-art process are shown. FIG. 3A illustrates a view of a nanosheet stack (NS) 240 along the nanosheet stack cross section (B-B′), in accordance with an example embodiment (all the views show three top and three bottom nanosheets except that in FIG. 3A, only two bottom nanosheets are shown, for illustrative convenience). Shallow trench isolation (STI) material 208 abuts the substrate 204. Nanosheet stack (NS) 240 includes alternating layers 212 of silicon germanium (SiGe) 213 and (e.g., Si) nanosheets 215. In one example embodiment, each silicon germanium (SiGe) layer has a thickness h1 of 10 nanometers (nm) and a width w1 of 20 nanometers, each nanosheet has a thickness h2 of 5 nanometers and a width w1 of 20 nanometers, and the height h3 of the STI material 208 is 55 nanometers. The stack height h4 can be 115 nm in an example, and the overall height h5 (STI plus stack) can be 170 nm. The pitch w2 can be, for example, 100 nm, with a distance w3 of 80 nm between adjacent stacks. The SiGe2 layer can have a thickness of 40 nm, for example. All dimensions are exemplary and non-limiting. Region 216 includes three stacked silicon germanium sub-layers, where the center sub-layer “SiGe2” numbered 241 has a higher percentage of germanium than the other SiGe layers/sub-layers (the upper and lower SiGe layers in 216 are the same as 213 but not separately numbered). For example, in one or more embodiments, SiGe2 has the Ge percentage ranging from 40-75% while the “regular” SiGe layers can include SiGe with the Ge percentage ranging from 15-35%, to allow selective etching. In one or more embodiments, the nanosheets are made of silicon; e.g., essentially undoped silicon. In one or more embodiments, the epitaxy in the source/drain regions has different polarity (i.e., n- or p-dopant types). The non-limiting exemplary flow indicates p-type top FET and n-type bottom FET; however, FET polarity is not limited and other embodiments could have, for example, an n-type top FET and a p-type bottom FET.

FIG. 3B illustrates a view 245 of the nanosheet stack (NS) 240 of FIG. 3A across the nanosheet stack cross section (A-A′), illustrating post gate and spacer formation, in accordance with an example embodiment. Note the gate 217 and gate spacer 219.

FIG. 3C illustrates a view 260 of the nanosheet stack (NS) 240 of FIG. 3B following reactive ion etching (ME) (i.e., of the source/drain (S/D) regions), in accordance with an example embodiment. The remaining portion (after ME) of the middle SiGe2 layer 241 of the three layers 216 is designated as 241A.

FIG. 3D illustrates a view 280 of the nanosheet stack (NS) 260 of FIG. 3C, following selective etching, in accordance with an example embodiment. In one example embodiment, the “SiGe2” layer 241A of FIG. 2C is selectively etched back and filled with a dielectric 243, followed by an etch back of the dielectric. For example, carry out selective removal of high-Ge % SiGe selective to low-Ge % SiGe using a gas phase HCl process or the like. It is noted that in one or more embodiments, the spacer material 219, such as silicon oxycarbonitride (SiOCN), and the fill material 243 are different. In one example embodiment, the spacer material is SiOCN and the fill material is silicon nitride (SiN).

FIG. 3E illustrates a view 286 of a second “air gap” embodiment of the gate and spacer formation of the nanosheet stack (NS). In the example “air gap” embodiment of FIG. 3E, after the step illustrated in FIG. 3C, a selective etch of the SiGe2 layer is performed. A non-conformal fill using a dielectric (such as SiN) is used followed by etch-back. In this “air gap” embodiment, the non-conformal dielectric deposition is used to intentionally leave void 664. The dielectric with an air gap or other void is designated as 243A. Given the teachings herein, the skilled artisan will be able to adapt known techniques to form air gaps or other voids.

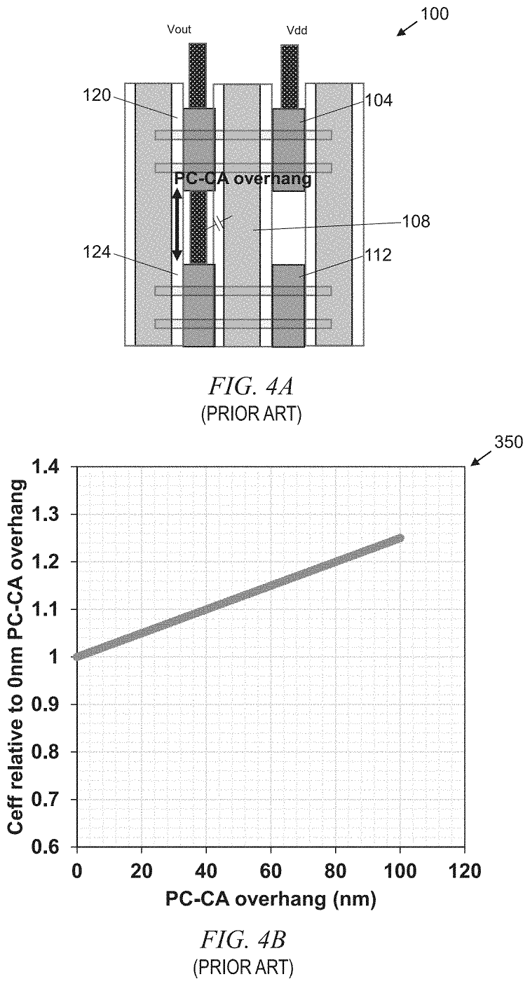

FIG. 4A replicates the physical structure of the conventional stacked field-effect transistor (FET) of FIG. 1A with the addition of an identification of the PC-CA overhang. Note that while FIG. 4A depicts prior art, the definition of PC-CA overhang is equally applicable to embodiments of the invention. As will be appreciated by the skilled artisan, PC-CA overhang is the length of contact metal that connects the top and bottom transistors. In the case of inverter design, the drains of the top and bottom transistors are connected in order to function as an inverter. Note that the non-limiting exemplary cases illustrated in the disclosure relate to inverters. Vertical nFET and pFET connections are unique in stacked-NS structures, which leads to additional gate-to-drain capacitance compared to conventional planar NS structures. For example, a front-up approach to monolithic integration requires 40 nanometer (nm) PC-CA overhang. FIG. 4B is a graph 350 that illustrates the impact of PC-CA overhang on the total effective capacitance C_{eff}, in prior art devices; this undesirable effect is advantageously alleviated in one or more embodiments. PC-CA overhang leads to additional gate-to-drain capacitance between nFET and pFET, and a 10% AC performance drop. (Results are based on the following assumptions from the literature: CA-PC capacitance is about 25% of the total effective capacitance C_{eff}; gate capacitance is about 20% of the total effective capacitance C_{eff}; and PC over source/drain S/D epitaxy is ˜50 nm.)

Referring again to FIGS. 1A and 1B, as noted, in the example embodiment of FIG. 1B, a portion of a conventional metal gate stack (e.g., adjacent the isolation region between the nFET and pFET) is replaced by a dielectric, such as silicon nitride (SiN). It is worth noting that one or more embodiments are implemented in the context of monolithic (self-aligned) flow rather than sequential flow. In one or more embodiments, for example, the gate sidewall spacer 219 is different as compared to sequential (wafer bonding) flow, as will be apparent to the skilled artisan from the teachings herein.

Referring again to the non-air-gap embodiment 150 of FIG. 1B, with optional buried power rail 116, note that air gap embodiments could also be formed with the optional buried power rail, if desired. Note that the gaps 664 (as seen in FIG. 3E, for example) are not limited to air; for example, if the fab line was in vacuum or dry nitrogen, the gaps could be vacuum or dry nitrogen. Any suitable atmosphere can be employed in one or more embodiments; vacuum should advantageously exhibit the lowest permittivity.

Comparing the non-air-gap and air-gap structures, respectively, the air gap (or other void) structure advantageously has lower capacitance, and hence better AC performance. On the other hand, the size of the void 664 in FIG. 3E is sensitive to the size of the dielectric portion 243A, and variability in void size can cause capacitance variability.

Given the discussion thus far, it will be appreciated that, in general terms, an exemplary semiconductor structure, according to an aspect of the invention, includes an inner field effect transistor (e.g., lower transistor in FIG. 1B) having an inner source (e.g., rightmost epitaxy 281 in FIG. 2B), an inner drain (e.g., leftmost epitaxy 281 in FIG. 2B), and a group of inner nanosheet channel structures (e.g., lower occurrences of 215 in FIG. 2B) interconnecting the inner source and the inner drain. Also included is an outer field effect transistor (e.g., upper transistor in FIG. 1B) having an outer source (e.g., rightmost epitaxy 283 in FIG. 2B), an outer drain (e.g., leftmost epitaxy 283 in FIG. 2B), and a group of outer nanosheet channel structures (e.g., upper occurrences of 215 in FIG. 2B) interconnecting the outer source and the outer drain. An isolation region 199 (e.g., SiO₂) is located between the inner field effect transistor and the outer field effect transistor. A metal gate stack 217 is located between the inner source and inner drain and between the outer source and the outer drain. The metal gate stack at least partially surrounds the inner and outer nanosheet channel structures. The metal gate stack has a dielectric region 243, 243A adjacent the isolation region.

In one or more embodiments, the semiconductor structure is a complementary metal oxide semiconductor (CMOS) structure such that the inner field effect transistor is either n-type or p-type and the outer field effect transistor is the other; i.e., if the outer is n, the inner is p; if the outer is p, the inner is n.

In the non-limiting example shown, the inner field effect transistor is n-type and the outer field effect transistor is p-type. A first electrically conductive pathway (e.g., 299D) couples the inner drain and the outer drain and forms an output node (e.g., with contact 299C). As will be appreciated by the skilled artisan, in a CMOS inverter, the PFET and NFET gates are coupled to form the input node. Here, while the common gate 217 has the dielectric 243, 243A, the dielectric is a replacement of the SiGe2 layer in the nanosheet stack. The metal gate 217 wraps around the nanosheet stack as can be seen in FIG. 2A, where metal gate does not overlap with the nanosheet stack (δ); this wrapping, non-overlapping region provides the electrical connection between the PFET and NFET parts of the gate in one or more embodiments. Thus, in one or more embodiments, the metal gate stack includes a side region (δ) electrically coupling the inner gate and the outer gate and forming an input node

One or more embodiments further include a first rail (e.g., Vdd seen in FIG. 2A) electrically coupled to the outer source; and a second rail (e.g., Vss seen in FIG. 2A) electrically coupled to the inner source.

Given the teachings herein, and referring to FIG. 6, the skilled artisan will appreciate that a circuit, such a CMOS circuit, will typically include many pairs of inner and outer transistors. Each pair is depicted schematically in FIG. 6 and can include, for example, stacked FET pairs such as 150 or 460. Thus, one or more embodiments further include a plurality of additional p-type inner field effect transistors having a plurality of additional inner sources, a plurality of additional inner drains, and a plurality of additional groups of inner nanosheet channel structures interconnecting the plurality of additional inner sources and the plurality of additional inner drains; a plurality of additional n-type outer field effect transistors having a plurality of additional outer sources, a plurality of additional outer drains, and a plurality of additional groups of outer nanosheet channel structures interconnecting the plurality of additional outer sources and the plurality of additional outer drains; a plurality of additional metal gate stacks between the plurality of additional inner sources and the plurality of additional inner drains and between the plurality of additional outer sources and the plurality of additional outer drains, the plurality of additional metal gate stacks at least partially surrounding the plurality of groups of additional inner and outer nanosheet channel structures; and a plurality of additional first electrically conductive pathways coupling the plurality of additional inner drains and the plurality of additional outer drains and forming a plurality of additional output nodes. The isolation region extends between the plurality of additional inner field effect transistors and the plurality of additional outer field effect transistors, and the plurality of additional metal gate stacks each has a dielectric region adjacent the isolation region. The plurality of additional outer sources are electrically coupled to the first rail (e.g., Vdd), and the plurality of additional inner sources are electrically coupled to the second rail (e.g., Vss). A power supply 999 can also be provided; for example, coupled to the first rail, with the second rail grounded (depending on the polarity of the transistors). The inputs and outputs of the additional stacked FET pairs (e.g., inverters) are omitted from the schematic of FIG. 6 but can be implemented in metal layers in a known manner.

In some cases, the second rail is a buried power rail (BPR) 116; however, as noted elsewhere, use of a BPR is optional.

In one or more embodiments, the dielectric region comprises silicon nitride.

In one or more embodiments, the inner and outer nanosheet channel structures comprise silicon.

In some cases, the dielectric region has a void 664 located therein; in a non-limiting example, the void comprises an air gap (however, as noted, the air gap is a non-limiting example and other types of void are possible).

One or more embodiments further include gate spacers 219 located adjacent the metal gate stack 217.

In a non-limiting example, the dielectric region comprises silicon nitride and the gate spacers comprise silicon oxycarbonitride (SiOCN).

Referring to FIG. 3A, one or more embodiments further include a substrate 204 (e.g., silicon or silicon-on-insulator (SOI)); the inner field effect transistor and the metal gate stack are formed on a substrate. Shallow trench isolation (STI) material 208 is recessed into the substrate adjacent the inner source and the inner drain.

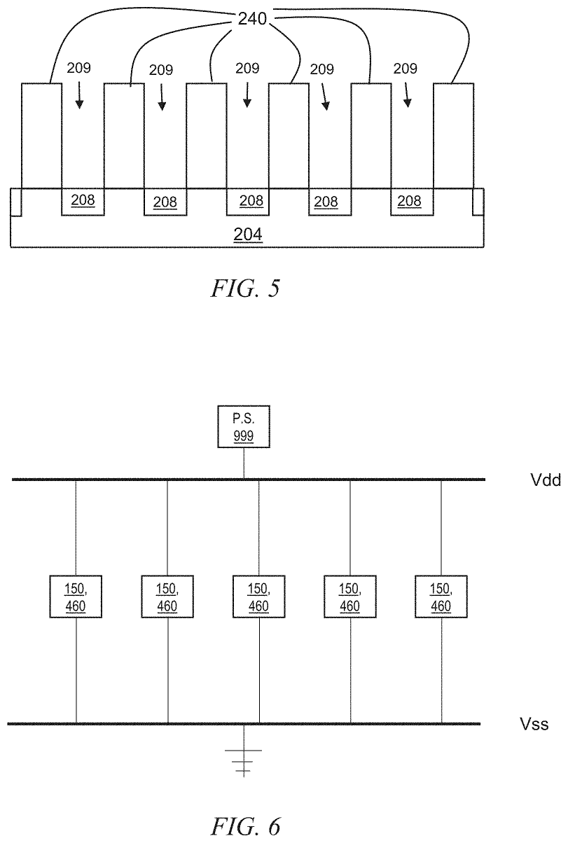

In another aspect, referring to FIGS. 3A-3E and FIG. 5, an exemplary method of forming a semiconductor structure includes providing a precursor structure 240 comprising a plurality of nanosheet stacks 240 on a substrate 204. Note that for convenience, number 240 is used to designate the view in FIG. 3A and the stack portion thereof in FIG. 5. The nanosheet stacks are separated by a plurality of gaps 209 partially filled with shallow trench isolation material 208. The nanosheet stacks include alternating layers of nanosheets 215 and spacers 213, including a central selectively etchable region (layer 241 of 216 as numbered in FIG. 3B). A further step includes forming dummy gate structures 217 and gate spacers 219 crosswise to the plurality of nanosheet stacks, as seen in view 245. A still further step includes etching back the nanosheet stack even with the gate spacers, as seen in view 260. An even further step includes selectively etching back the central selectively etchable region to form an etched-back area, and filling the etched-back area with dielectric material 243 or 243A, as seen in FIG. 3D view 280 and FIG. 3E view 286.

In one or more embodiments, in the providing step, the nanosheets comprise silicon, the spacers comprise SiGe with the Ge percentage ranging from 15-35%, and the central selectively etchable region comprises SiGe with the Ge percentage ranging from 40-75%.

In one or more embodiments, filling the etched-back area with dielectric material comprises filling the etched-back area with silicon nitride.

In one or more embodiments, forming the gate spacers comprises depositing the gate spacers as silicon oxycarbonitride.

Filling the etched-back area with dielectric material can include completely filling the etched-back area with dielectric material, as in FIG. 3D, or only partially filling the etched-back area with dielectric material, such that a void is present in the dielectric material, as in FIG. 3E.

Semiconductor device manufacturing includes various steps of device patterning processes. For example, the manufacturing of a semiconductor chip may start with, for example, a plurality of CAD (computer aided design) generated device patterns, which is then followed by effort to replicate these device patterns in a substrate. The replication process may involve the use of various exposing techniques and a variety of subtractive (etching) and/or additive (deposition) material processing procedures. For example, in a photolithographic process, a layer of photo-resist material may first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) may experience some changes in their solubility to certain solutions. The photo-resist may then be developed in a developer solution, thereby removing the non-irradiated (in a negative resist) or irradiated (in a positive resist) portions of the resist layer, to create a photo-resist pattern or photo-mask. The photo-resist pattern or photo-mask may subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, and reactive ion etching (RIE), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. For example, the skilled artisan will be familiar with epitaxial growth, self-aligned contact formation, formation of high-K metal gates, and so on. The term “high-K” has a definite meaning to the skilled artisan in the context of high-K metal gate (HKMG) stacks, and is not a mere relative term. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1^{st} Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

Those skilled in the art will appreciate that the exemplary structures discussed above can be distributed in raw form (i.e., a single wafer having multiple unpackaged chips), as bare dies, in packaged form, or incorporated as parts of intermediate products or end products.

An integrated circuit in accordance with aspects of the present inventions can be employed in essentially any application and/or electronic system. Given the teachings of the present disclosure provided herein, one of ordinary skill in the art will be able to contemplate other implementations and applications of embodiments disclosed herein.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods may occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76(b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A semiconductor structure comprising:
an inner field effect transistor having an inner source, an inner drain, and a group of inner nanosheet channel structures interconnecting the inner source and the inner drain;
an outer field effect transistor having an outer source, an outer drain, and a group of outer nanosheet channel structures interconnecting the outer source and the outer drain;
an isolation region between the inner field effect transistor and the outer field effect transistor; and
a metal gate stack between the inner source and inner drain and between the outer source and the outer drain, the metal gate stack at least partially surrounding the inner and outer nanosheet channel structures, the metal gate stack having a dielectric region adjacent the isolation region.

2. The semiconductor structure of claim 1, wherein the inner field effect transistor comprises one of an n-type field effect transistor and a p-type field effect transistor and the outer field effect transistor comprises another one of an n-type field effect transistor and a p-type field effect transistor.

3. The semiconductor structure of claim 2, wherein the inner field effect transistor comprises the n-type field effect transistor and the outer field effect transistor comprises the p-type field effect transistor, further comprising a first electrically conductive pathway coupling the inner drain and the outer drain and forming an output node, wherein the metal gate stack includes a side region electrically coupling the inner gate and the outer gate and forming an input node.

4. The semiconductor structure of claim 3, further comprising:
a first rail electrically coupled to the outer source; and
a second rail electrically coupled to the inner source.

5. The semiconductor structure of claim 4, further comprising:
a plurality of additional p-type inner field effect transistors having a plurality of additional inner sources, a plurality of additional inner drains, and a plurality of additional groups of inner nanosheet channel structures interconnecting the plurality of additional inner sources and the plurality of additional inner drains;
a plurality of additional n-type outer field effect transistors having a plurality of additional outer sources, a plurality of additional outer drains, and a plurality of additional groups of outer nanosheet channel structures interconnecting the plurality of additional outer sources and the plurality of additional outer drains;
a plurality of additional metal gate stacks between the plurality of additional inner sources and the plurality of additional inner drains and between the plurality of additional outer sources and the plurality of additional outer drains, the plurality of additional metal gate stacks at least partially surrounding the plurality of additional groups of inner and outer nanosheet channel structures; and
a plurality of additional first electrically conductive pathways coupling the plurality of additional inner drains and the plurality of additional outer drains and forming a plurality of additional output nodes; and
wherein:
the isolation region extends between the plurality of additional inner field effect transistors and the plurality of additional outer field effect transistors, the plurality of additional metal gate stacks each having a dielectric region adjacent the isolation region;
the plurality of additional outer sources are electrically coupled to the first rail;
the plurality of additional inner sources are electrically coupled to the second rail.

6. The semiconductor structure of claim 5, further comprising a power supply coupled to the first rail.

7. The semiconductor structure of claim 4, wherein the second rail comprises a buried power rail.

8. The semiconductor structure of claim 1, wherein the dielectric region comprises silicon nitride.

9. The semiconductor structure of claim 8, wherein the inner and outer nanosheet channel structures comprise silicon.

10. The semiconductor structure of claim 1, wherein the dielectric region has a void located therein.

11. The semiconductor structure of claim 10, wherein the void comprises an air gap.

12. The semiconductor structure of claim 1, further comprising gate spacers located adjacent the metal gate stack.

13. The semiconductor structure of claim 12, wherein the dielectric region comprises silicon nitride and the gate spacers comprise silicon oxycarbonitride (SiOCN).

14. The semiconductor structure of claim 1, further comprising:
a substrate, wherein the inner field effect transistor and the metal gate stack are formed on a substrate; and
shallow trench isolation material recessed into the substrate adjacent the inner source and the inner drain.

15. A method of forming a semiconductor structure, comprising:
providing a precursor structure comprising a plurality of nanosheet stacks on a substrate, the nanosheet stacks being separated by a plurality of gaps partially filled with shallow trench isolation material, the nanosheet stacks comprising alternating layers of nanosheets and spacers, including a central selectively etchable region;
forming dummy gate structures and gate spacers crosswise to the plurality of nanosheet stacks;
etching back the nanosheet stack even with the gate spacers; and
selectively etching back the central selectively etchable region to form an etched-back area, and filling the etched-back area with dielectric material.

16. The method of claim 15, wherein, in the providing step, the nanosheets comprise silicon, the spacers comprise SiGe with the Ge percentage ranging from 15-35%, and the central selectively etchable region comprises SiGe with the Ge percentage ranging from 40-75%.

17. The method of claim 16, wherein filling the etched-back area with dielectric material comprises filling the etched-back area with silicon nitride.

18. The method of claim 17, wherein forming the gate spacers comprises depositing the gate spacers as silicon oxycarbonitride.

19. The method of claim 15, wherein filling the etched-back area with dielectric material comprises completely filling the etched-back area with dielectric material.

20. The method of claim 15, wherein filling the etched-back area with dielectric material comprises only partially filling the etched-back area with dielectric material, such that a void is present in the dielectric material.
